(19) United States
(12) Patent Application Publication
(10) Pub. No.: US 2013/0015465 A1
(43) Pub. Date: Jan. 17, 2013

(54) NITRIDE SEMICONDUCTOR LIGHT-EMITTING DEVICE

(71) Applicant: Jae-hoon LEE, Suwon-si (KR)

(72) Inventor: Jae-hoon LEE, Suwon-si (KR)

(73) Assignee: SAMSUNG ELECTRONICS CO., LTD.

(21) Appl. No.: 13/547,996

(22) Filed: Jul. 12, 2012

(30) Foreign Application Priority Data
Jul. 12, 2011 (KR) 10-2011-0068962

(51) Int. Cl. H01L 33/32

(52) U.S. Cl. 257/76; 257/E33.025

(57) ABSTRACT

A nitride light-emitting device includes an N-type nitride semiconductor layer; an active layer disposed on the N-type nitride semiconductor layer; and a P-type nitride semiconductor layer disposed on the active layer. The P-type nitride semiconductor includes a heterojunction structure having a GaN layer and an N-type AlₓIn_{y}GaN layer that is doped with an N-type dopant, and a two-dimensional electron gas (2DEG) layer formed in an interface between the GaN layer and the N-type AlₓIn_{y}GaN layer.

### CROSS-REFERENCE TO RELATED APPLICATIONS

This application claims the benefit of Korean Patent Application No. 10-2011-0068962, filed on Jul. 12, 2011, in the Korean Intellectual Property Office, the disclosures of which are incorporated herein in their entirety by reference.

### BACKGROUND

1. Field

The present disclosure relates to a light-emitting device, and more particularly, to a nitride light-emitting device.

2. Description of the Related Art

Nitride light-emitting diodes (LEDs) are semiconductor devices capable of emitting various colors of light by constituting a light-emitting source with a PN junction of a nitride semiconductor. Nitride LEDs have been continuously developed so that the nitride LEDs are used not only for a short-wavelength light but also for a long-wavelength light. A nitride LED may be widely applied not only to an optical device but also to an electronic device to benefit from physical advantages of the nitride LED.

As blue LEDs formed of a nitride semiconductor are introduced, application of LEDs becomes wider, and the LEDs are used in various fields, such as keypads, backlights of liquid crystal display (LCD) devices, traffic lights, airplanes, cars, and lights. In particular, white LEDs may replace existing incandescent bulbs and fluorescent lights, which will be a form of revolution in lighting.

Since a nitride light-emitting diode (LED) has a limitation in the P-doping of a P-type semiconductor, a need for technologies for reducing a current collapse phenomenon by decreasing a turn-on voltage and improving the current diffusion effect exists.

### SUMMARY

Provided is a nitride light-emitting device capable of improving a current diffusion effect and increasing optical power.

Additional aspects will be set forth in part in the description which follows and, in part, will be apparent from the description, or may be learned by practice of the presented embodiments.

An aspect of the present disclosure encompasses a nitride light-emitting device. The nitride light-emitting device includes an N-type nitride semiconductor layer; a P-type nitride semiconductor layer; and an active layer formed between the N-type nitride semiconductor layer and the p-type nitride semiconductor layer. A heterojunction structure is formed in the P-type nitride semiconductor layer. The hetero junction structure includes a GaN layer and an N-type AlₓIn_{y}GaN layer that is doped with an N-type dopant, wherein 0≦x≦1, 0≦y≦1and x+y=1, and a two-dimensional electron gas (2DEG) layer formed in an interface between the GaN layer and the N-type AlₓIn_{y}GaN layer.

The P-type nitride semiconductor layer comprises a P-type clad layer formed on the active layer and a P-type contact layers formed on the P-type clad layer, wherein the heterojunction structure is formed inside the P-type contact layer or the P-type clad layer. For example, the P-type contact layer is formed of P⁺-GaN, and the heterojunction structure is formed inside the P-type contact layer.

In the heterojunction structure, the GaN layer is formed at the active layer.

The GaN layer is an undoped layer. The GaN layer has a thickness of about 5 nm to about 50 nm.

The N-type dopant of the N-AlₓIn_{y}GaN layer is Si. The N—AlₓIn_{y}GaN layer is formed of AlGaN comprising Al content of from about 15 to about 45%. The N—AlₓIn_{y}GaN layer has a thickness in a range of about 10 nm to about 50 nm.

Another aspect of the present disclosure relates to the nitride light-emitting device further including an N-type electrode formed on the N-type nitride semiconductor layer; and a P-type electrode formed on the P-type nitride semiconductor layer and formed of a transparent conductive material, wherein light is emitted through the P-type electrode.

According to another aspect of the disclosure, the nitride light-emitting device further includes an N-type electrode formed on the N-type nitride semiconductor layer; and a P-type electrode formed on the P-type nitride semiconductor layer, wherein the nitride light-emitting device may have an epi-down type vertical structure.

According to another aspect of the disclosure, the nitride light-emitting device further includes an N-type electrode formed on the N-type nitride semiconductor layer; a P-type electrode formed on the P-type nitride semiconductor layer; and a wiring substrate bonded to the P-type electrode, wherein the nitride light-emitting device may have an array having a flip chip structure.

In the nitride light-emitting device according to the embodiments of the disclosure, a heterojunction structure of N—AlₓIn_{y}GaN/GaN is formed in a P-type nitride semiconductor layer to induce 2DEG, thereby increasing a current diffusion effect in the P-type nitride semiconductor layer due to a high carrier mobility of the 2DEG. Thus, even though a high power is supplied, a current crowding phenomenon is prevented, and thus reliability of a nitride light-emitting device may be increased. Also, a tunneling junction of N⁺/P⁺ is formed between the heterojunction structure and the P-type nitride semiconductor layer, and thus efficiency of hole injection into an active layer may be increased, thereby increasing light power.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic view illustrating a structure of a nitride light-emitting device, according to an embodiment of the disclosure;

FIG. 2 is an energy band diagram of the nitride light-emitting device of FIG. 1;

FIG. 3 is a graph showing optical characteristics of the nitride light-emitting device of FIG. 1;

FIG. 4 is a graph for explaining the nitride light-emitting device of FIG. 1 influenced by Joule heating;

FIG. 5 is a graph showing electrical characteristics of the nitride light-emitting device of FIG. 1;

FIG. 6 is a graph showing electrical characteristics of the nitride light-emitting device of FIG. 1 according to existence of a P-type contact layer;

FIG. 7 is a graph showing electrical characteristics of the nitride light-emitting device of FIG. 1 according to a thickness of AlGaN;

FIG. 8 is a graph showing electrical characteristics of the nitride light-emitting device of FIG. 1 according to a thickness of GaN;

FIG. 9 is a schematic view illustrating a vertical type nitride light-emitting device, according to another embodiment of the disclosure and

FIG. 10 is a schematic view illustrating a nitride light-emitting device including an array having a flip chip structure, according to still another embodiment of the disclosure.

### DETAILED DESCRIPTION

Now, exemplary embodiments will be described in detail with reference to the accompanying drawings. In the drawings, like reference numerals in the drawings denote like elements, and the thicknesses of layers and regions are exaggerated for clarity.

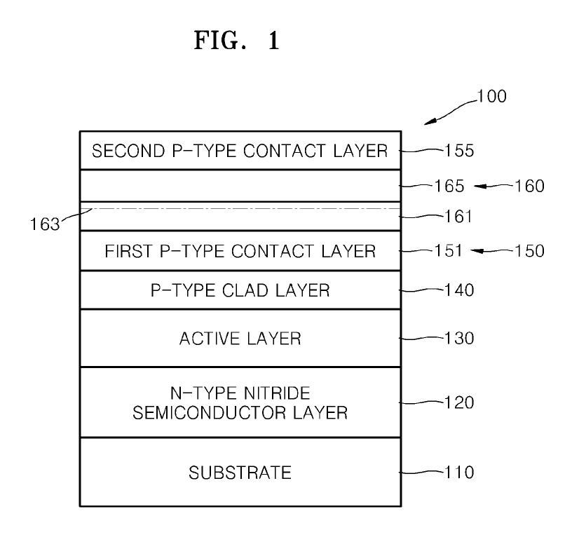

FIG. 1 is a schematic view illustrating a structure of a nitride light-emitting device 100, according to an embodiment.

Referring to FIG. 1, the nitride light-emitting device 100 includes a substrate 110, an N-type nitride semiconductor layer 120, an active layer 130, a P-type clad layer 140, a P-type contact layer 150, and a heterojunction structure 160 formed inside the P-type contact layer 150.

The substrate 110 may be, for example, a sapphire (Al₂O₃) substrate, a SiC substrate, a GaN substrate, or the like. A concavo-convex pattern may be formed in an upper surface of the substrate 110 in order to reduce lattice mismatch between the substrate 110 and nitride semiconductor layers growing on the substrate 110 and to increase light extraction efficiency.

The N-type nitride semiconductor layer 120 may be, for example, a GaN layer or a GaN/AlGaN layer doped with an N-type dopant. A buffer layer (not shown) used in crystal growth of the N-type nitride semiconductor layer 120 may be interposed between the substrate 110 and the N-type nitride semiconductor layer 120. The active layer 130 may have, for example, a multi-quantum well structure including an InGaN/GaN layer.

The P-type clad layer 140 may have a strained layer superlattices (SLS) structure of AlGaN/GaN doped with a P-type dopant. Alternatively, the P-type clad layer 140 may have an SLS structure or may be a P-GaN layer.

The P-type contact layer 150 may be a P⁺-GaN layer doped with a P-type dopant. When the heterojunction structure 160 is formed in the P-type contact layer 150, the P-type contact layer 150 is divided into a first P-type contact layer 151 disposed at a lower side of the heterojunction structure 160 and a second P-type contact layer 155 disposed at an upper side of the heterojunction structure 160. The first P-type contact layer 151 and the second P-type contact layer 155 may have the same composition, but the present invention is not limited thereto.

The heterojunction structure 160 may have an N—AlₓIn_{y}GaN/GaN structure, wherein 1≦x≦1, 0≦y≦1, and x+y=1. For example, the heterojunction structure 160 may have a bonding structure between an undoped GaN layer 161 and an N-type AlGaN layer 165. The heterojunction structure 160 is formed in the P-type contact layer 150 to increase current diffusion and hole injection efficiency. A thickness of the undoped GaN layer 161 may be determined by considering formation of a two-dimensional electron gas (2DEG) layer 163 or a tunneling phenomenon. The thickness of the undoped GaN layer may be, for example, in the range of about 5 nm to about 50 nm. The thickness of the undoped GaN layer 161 may preferably be in the range of about 7 nm to about 15 nm. The N-type AlGaN layer 165 may be formed of an AlGaN layer doped with an N-type dopant such as Si. As the amount of Al in the N-type AlGaN layer 165 increases, an electronic intensity of the 2DEG layer 163 increases. In this case, a crystal quality of the AlGaN layer may deteriorate, and thus the thickness of the undoped GaN layer 161 may be determined by considering the crystal quality of the AlGaN layer. For example, the N-type AlGaN layer 165 may include Al content of from about 15 to about 45% and may be formed to have a thickness of about 10 nm to about 50 nm. The N-type AlGaN layer 165 may preferably be formed to have a thickness of about 15 nm to about 30 nm.

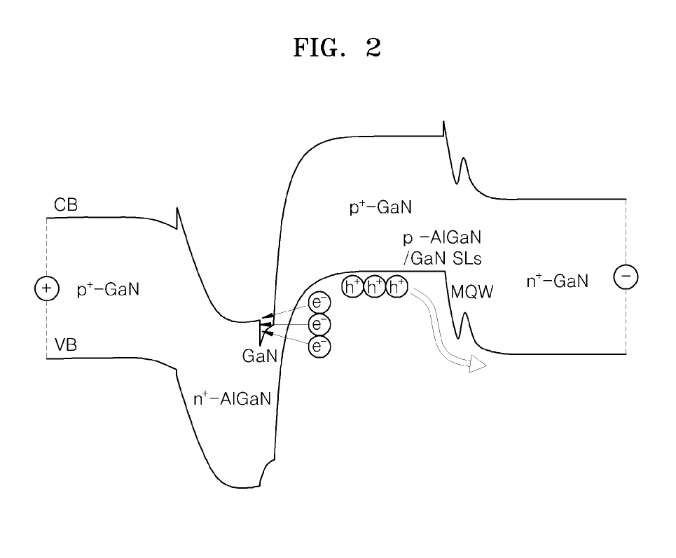

FIG. 2 is an energy band diagram of the nitride light-emitting device 100 of FIG. 1. Referring to FIG. 2, the 2DEG layer 163 is formed in an interface between the undoped GaN layer 161 and the N-type AlGaN layer 165 due to discontinuity of an energy band between the undoped GaN layer 161 and the N-type AlGaN layer 165. Since the 2DEG layer 163 has a high carrier mobility, current diffusion in the P-type contact layer 150 improves. As the current diffusion improves, even though high power is supplied, a current crowding phenomenon is prevented, and thus reliability of the nitride light-emitting device 100 increases. Also, since the 2DEG layer 163 is an area including too many electrons, a tunneling junction of N⁺/P⁺ is formed between the heterojunction structure 160 and the P-type contact layer 150, and thus efficiency of hole injection into the active layer 130 increases, thereby imparting a higher brightness at the same current intensity.

In the current embodiment, the heterojunction structure 160 has a bonding structure between the undoped GaN layer 161 and the N-type AlGaN layer 165, but the present disclosure is not limited thereto. For example, a GaN layer doped with GaN may be replaced with the undoped GaN layer 161 within a range having an energy band structure in which the 2DEG layer 163 may be formed in the interface between the undoped GaN layer 161 and the N-type AlGaN layer 165. Alternatively, an N—AlInGaN layer formed of AlInGaN doped with an N-type dopant or an N—AlInN layer formed of AlInN doped with an N-type dopant may be replaced with the undoped GaN layer 161.

Meanwhile, in the current embodiment, an N-type electrode (not shown) may be formed at a side of the N-type nitride semiconductor layer 120, and a P-type electrode (not shown) may be formed at a side of the P-type contact layer 150. If the substrate 110 is a conductive substrate such as a SiC substrate or a GaN substrate, an N-type electrode (not shown) may be formed on a reverse side of the substrate 110.

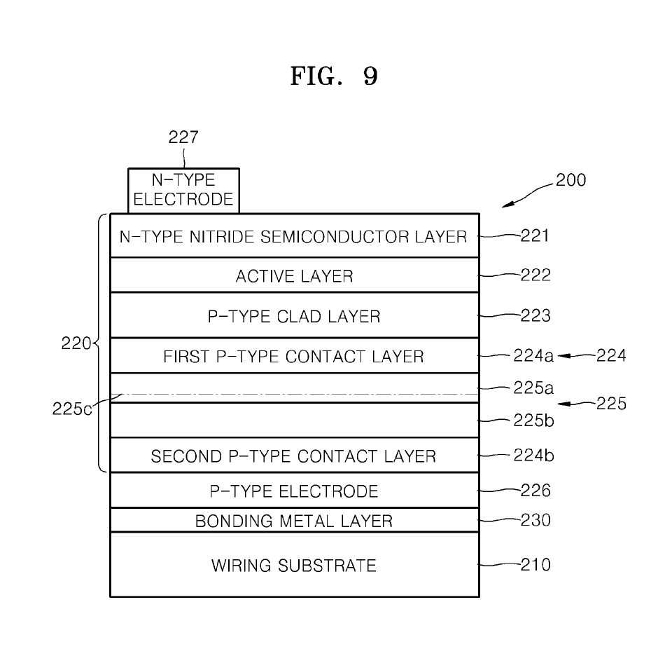

The P-type electrode (not shown) may be a transparent electrode that is entirely doped on an upper surface of a P-type contact layer 190 and may be formed of, for example, a transparent conductive material such as indium tin oxide (ITO) or zinc oxide (ZnO). In this case, the nitride light-emitting device 100 may have a structure in which light is emitted upward to the nitride light-emitting device 100. Alternatively, the nitride light-emitting device 100 may have an epi-down type vertical structure in which light is emitted toward the N-type nitride semiconductor layer 120, similar to a nitride light-emitting device 200 illustrated in FIG. 9 according to another embodiment. In this case, the P-type electrode (not shown) may be formed of silver (Ag), aluminum (Al), or an alloy thereof, or alternatively, the P-type electrode (not shown) may be formed of a metal having a high reflectivity.

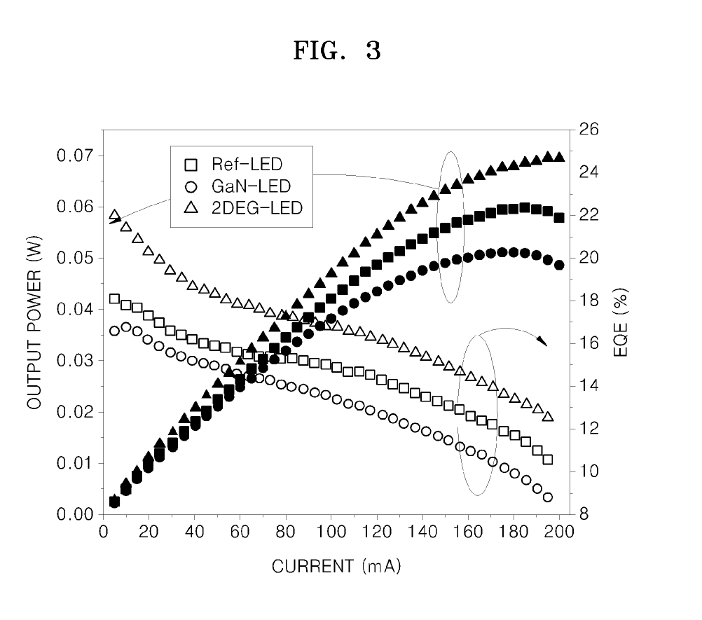

FIGS. 3 through 8 are graphs showing optical and electrical characteristics of the nitride light-emitting device 100.

In FIGS. 3 through 5, a Ref-LED of a comparative example is a general nitride light-emitting device in which no other layer is formed in a P⁺-GaN layer which is a P-type contact layer, and a GaN-LED of another comparative example is a nitride light-emitting device in which only an undoped GaN layer is formed in a P⁺-GaN layer which is a P-type contact layer. Meanwhile, a 2DEG-LED, which is an example of the nitride light-emitting device 100 according to the embodiment, is a nitride light-emitting device in which the heterojunction structure 160 (see FIG. 1) including N—AlGaN and undoped GaN is formed in the P⁺-GaN layer which is a P-type contact layer.

FIG. 3 is a graph showing optical characteristics with respect to the Ref-LED, the GaN-LED, and the 2DEG-LED.

Referring to FIG. 3, the Ref-LED, the GaN-LED, and the 2DEG-LED show optical power values of 9.7 mW, 9.2 mW, and 11.4 mW respectively at a current density of 20 mA. In the 2DEG-LED, which is an example of the nitride light-emitting device 100 according to the present embodiment, a brightness is increased by about 17% compared to the Ref-LED which is a general light-emitting device. Also, the Ref-LED, the GaN-LED, and the 2DEG-LED show external quantum efficiency (EQE) values of 17.3%, 16.2%, and 20.3% respectively. In the 2DEG-LED, which is an example of the nitride light-emitting device 100 according to the present embodiment, the EQE value is increased by 3% compared to the Ref-LED which is the general light-emitting device. Such an increase in brightness may result from an increase in current diffusion due to the formation of the 2DEG layer 163 by the heterojunction structure 160 of N—AlGaN/GaN formed in the P-type contact layer 150. The increase of the brightness may also result from an increase in high electron intensity of the 2DEG layer 163 and an increase in efficiency of hole injection into the active layer 130 due to a tunneling junction between the heterojunction structure 160 and the P-type contact layer 150.

In FIG. 3, at a relatively high current density of about 200 mA, the 2DEG-LED shows an optical power value that is increased by about 20% compared to that of the Ref-LED, which shows that, as described above, current diffusion is improved by the 2DEG layer 163 formed in the heterojunction structure 160 of N—AlGaN/GaN and thus scattering of electrons is reduced and a current crowding phenomenon is prevented.

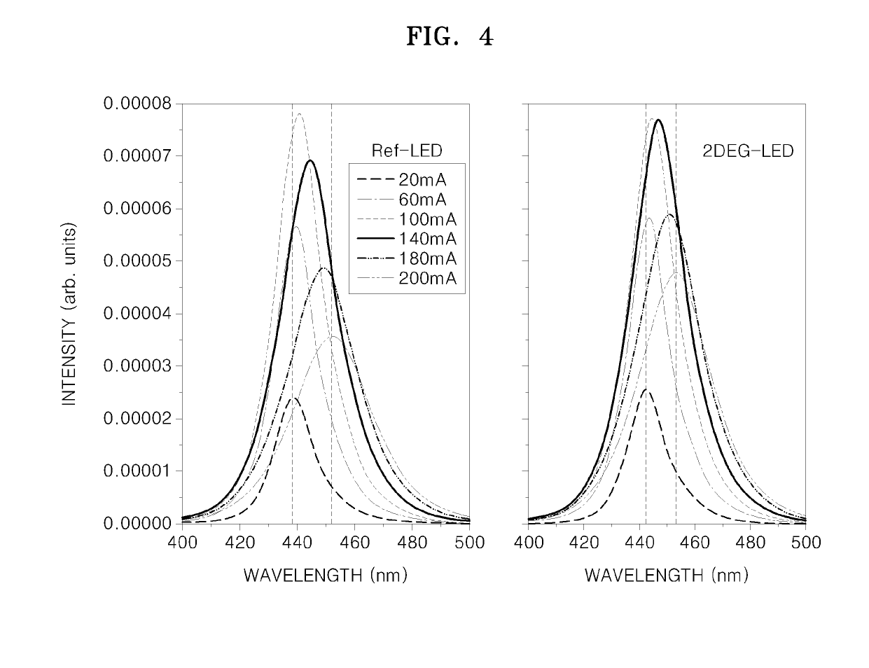

FIG. 4 is a graph for explaining changes in wavelengths with respect to heat emission of the Ref-LED, the GaN-LED, and the 2DEG-LED, which shows influence due to Joule heating.

Referring to FIG. 4, when current density increases from 20 mA to 200 mA, the Ref-LED shows that the wavelength changes from 438 nm to 452 nm, by 14 nm. Meanwhile, the 2DEG-LED shows that the wavelength changes from 443 nm to 453 nm, by 10 nm. That is, variation in the wavelength of the 2DEG-LED is smaller than that of the Ref-LED, which shows that as the current diffusion effect increases by the 2DEG layer 163 formed in the heterojunction structure 160 of N—AlGaN/GaN, the current crowding phenomenon is prevented, and thus heat emission decreases. As such, in the 2DEG-LED, that is, in the nitride light-emitting device 100 according to the present embodiment, current diffusion may increase, and thus reliability may increase even as a high power LED.

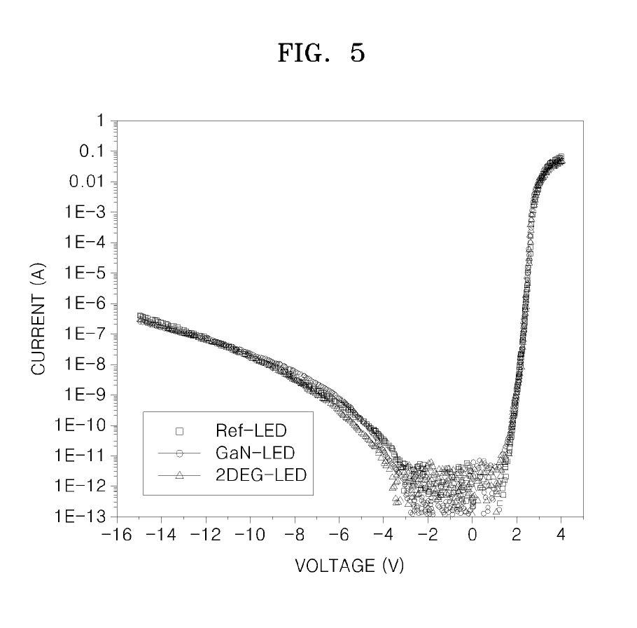

FIG. 5 is a graph showing electrical characteristics with respect to the Ref-LED, the GaN-LED, and the 2DEG-LED. In the nitride light-emitting device 100 according to the embodiment, the heterojunction structure 160 of N—AlGaN/GaN is formed in the P-type contact layer 150, and thus an operating current may increase slightly or a leakage current may increase. Referring to FIG. 5, the Ref-LED, the GaN-LED, and the 2DEG-LED respectively show operating voltages of 3.20 V, 3.24 V, and 3.28 V at a current density of 20 mA. That is, a difference in the operating voltages between the 2DEG-LED and the Ref-LED is as small as about 0.08 V. Meanwhile, the Ref-LED, the GaN-LED, and the 2DEG-LED show leakage currents of −18 nA, −20 nA, and −17 nA respectively at a counter voltage of −10 V. That is, a difference in the leakage currents between the 2DEG-LED and the Ref-LED is as small as about 1 nA. Accordingly, an increase in the operating current and an increase in the leakage current due to the formation of the heterojunction structure 160 of N—AlGaN/GaN in the P-type contact layer 150 may be insignificant.

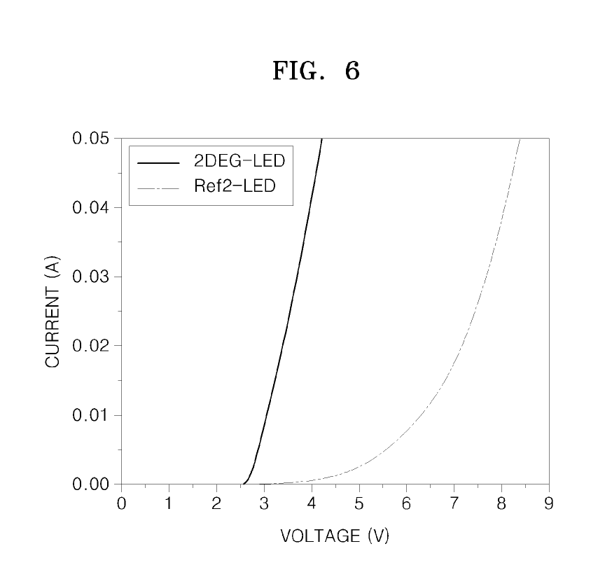

FIG. 6 is a graph showing an electrical characteristic of the nitride light-emitting device 100 where the heterojunction structure 160 is formed. In FIG. 6, the 2DEG-LED is an example of the nitride light-emitting device 100 according to the present embodiment. The 2DEG-LED is a nitride light-emitting device in which the heterojunction structure 160 (see FIG. 1) of n-AlGaN/GaN is formed in the P⁺-GaN layer, which is a P-type contact layer, and an ITO electrode is formed on the P⁺-GaN layer. An Ref2-LED of a comparative example is a nitride light-emitting device in which the heterojunction structure 160 (see FIG. 1) of n-AlGaN/GaN is formed between the Pt GaN layer which is a P-type contact layer and the ITO electrode. Referring to FIG. 6, while the 2DEG-LED shows an operating voltage of 3.28 V at a current density of 20 mA, the Ref2-LED shows an operating voltage as high as about 7 V. Thus, when a heterojunction structure of n-AlGaN/GaN is formed inside a P-type contact layer such as P⁺-GaN, an operating voltage of a light-emitting device may decrease.

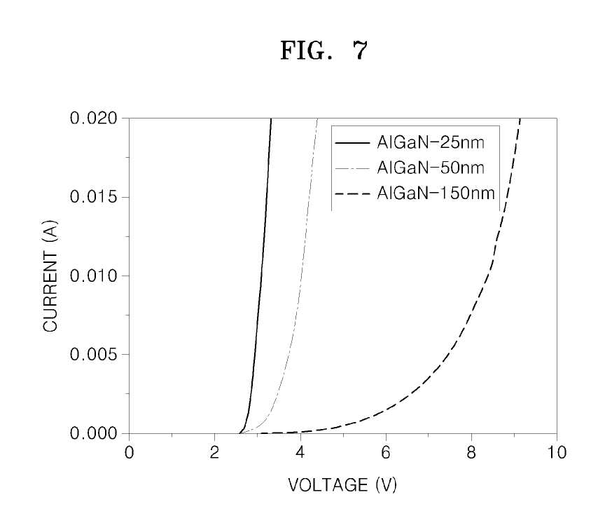

FIG. 7 is a graph showing electrical characteristics of the nitride light-emitting device 100 according to a thickness of the N-type AlGaN layer of the heterojunction structure. Referring to FIG. 7, as the thickness of the AlGaN layer increases, an operational voltage of the nitride light-emitting device 100 increases. For example, when the thickness of the AlGaN layer is 50 nm, the operational voltage is about 4 V, and when the thickness of the AlGaN layer is about 25 nm, the operational voltage is about 3 V. Accordingly, if the thickness of the AlGaN layer is below 30 nm, the operational voltage may be less than 4 V. Meanwhile, if the thickness of the AlGaN layer is too small, the operational voltage is low, but a 2DEG decreases, and thus other advantageous effects due to the heterojunction structure may be reduced. Accordingly, the thickness of the AlGaN layer may be in the range of about 10 nm to about 50 nm, and may preferably be in the range of 15 nm to about 30 nm, thereby decreasing the operational voltage of the nitride light-emitting device 100.

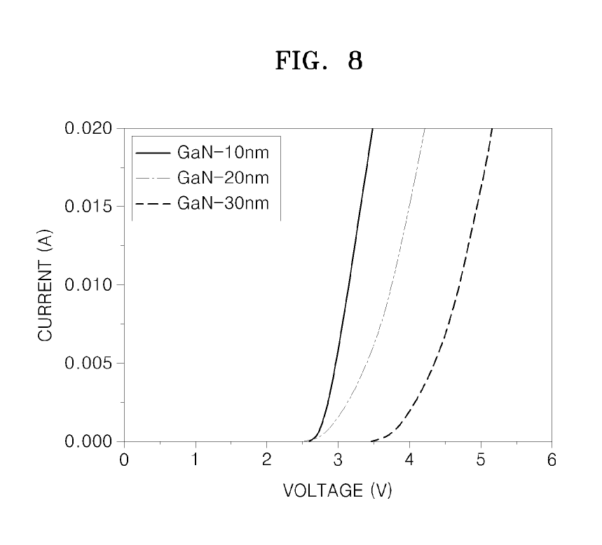

FIG. 8 is a graph showing electrical characteristics of the nitride light-emitting device 100 according to a thickness of the GaN layer of the heterojunction structure. Referring to FIG. 8, as the thickness of the GaN layer increases, an operational voltage of the nitride light-emitting device 100 increases. For example, when the thickness of the GaN layer is 20 nm, the operational voltage of the nitride light-emitting device 100 is about 4 V. Meanwhile, a depth of a 2DEG is about 7 nm. Accordingly, when the thickness of the GaN layer is in the range of about 7 nm to about 15 nm, formation of the 2DEG may be secured and the operational voltage may decrease.

In the current embodiment, the heterojunction structure 160 of N—AlGaN/GaN is formed in the P-type contact layer 150 such as P⁺-GaN, but the present invention is not limited thereto, and the heterojunction structure 160 may be formed in the P-type clad layer 140.

FIG. 9 is a schematic view illustrating a nitride light-emitting device 200, according to another embodiment. Referring to FIG. 9, the nitride light-emitting device 200 has a vertical type structure including a wiring substrate 210 and a nitride epitaxial structure 220 formed on the wiring substrate 210.

The nitride epitaxial structure 220 substantially has the same structure as the N-type nitride semiconductor structure layer 120 illustrated in FIG. 1 except for the order in which the layers are stacked. That is, the nitride epitaxial structure 220 may include an N-type nitride semiconductor layer 221, an active layer 222, a P-type clad layer 223, a first P-type contact layer 224a, an undoped GaN layer 225a, an N-type AlGaN layer 225b, and a second P-type contact layer 224b that are sequentially stacked in the stated order on a growth substrate (not shown) such as a sapphire substrate, a SiC substrate, or a GaN substrate. Meanwhile, the growth substrate on which the nitride epitaxial structure 220 is grown may be removed by using laser lift off (LLO) in order to improve heat conductivity. Referring to FIG. 9, an upper surface of the nitride epitaxial structure 220 is a surface from which light is emitted, and a topographic image may be reversed by using a concavo-convex structure on the growth substrate in order to further increase a light extraction efficiency.

The wiring substrate 210 may be a conductive substrate formed of a metal, for example, copper (Cu), chrome (Cr), or nickel (Ni), or alternatively, the wiring substrate 210 may be a Si or GaAs semiconductor substrate. The wiring substrate 210 is bonded to the epitaxial structure 220 by using a bonding metal layer 230 formed of a material such as Au—Au or AuSn. Instead of the wafer bonding using the bonding metal layer 230, a lower surface of the nitride epitaxial structure 220 may be plated with a metal such as Cu, Ni, or Cr to a thickness of several tens of pm to form the wiring substrate 210.

In order to achieve an electrical connection, a P-type electrode 226 may be formed on a lower surface, as shown in FIG. 9, of the second P-type contact layer 224b, the P-type electrode 226 may be connected to the wiring substrate 210 through the bonding metal layer 230, and an N-type electrode 227 may be formed in at least a part of the N-type nitride semiconductor layer 221.

As described above with reference to FIGS. 1 through 8, a heterojunction structure 225 including the undoped GaN layer 225a and the N-type AlGaN layer 225b is formed between the first P-type contact layer 224a and the second P-type contact layer 224b, and a 2DEG layer 225c may be formed adjacent to an interface between the undoped GaN layer 225a and the N-type AlGaN layer 225b, and thus current diffusion may increase. Also, a tunneling junction of N⁺/P⁺ is formed between the heterojunction structure 225 and the P-type contact layer 224, and thus efficiency of hole injection into the active layer 222 may increase, thereby providing a higher brightness at the same current density.

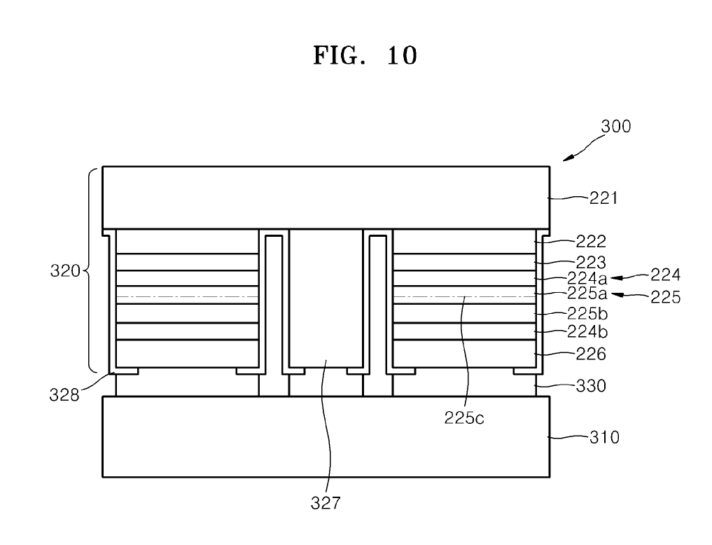

FIG. 10 is a schematic view illustrating a nitride light-emitting device 300 according to another embodiment.

Referring to FIG. 10, the nitride light-emitting device 300 has an array structure of a flip-chip type light-emitting device, and an individual unit light-emitting device may be substantially the same as the nitride light-emitting device 200 having a vertical type structure described with reference to FIG. 9. For example, each nitride epitaxial structure 320 may be formed, as described above, by sequentially stacking the N-type nitride semiconductor layer 221, the active layer 222, the P-type clad layer 223, the first P-type contact layer 224a, the undoped GaN layer 225a, the N-type AlGaN layer 225b, the second P-type contact layer 224b, and the P-type electrode 226 on the growth substrate (not shown) and then etching the above layers to be divided into individual nitride light-emitting devices. Also, the growth substrate on which the nitride epitaxial structure 320 is grown may be removed. An upper surface of the nitride epitaxial structure 320 is a surface from which light is emitted, and a topographic image may be reversed by using a concavo-convex structure on the growth substrate in order to further increase a light extraction efficiency.

The P-type electrode 226 and an N-type contact electrode 327 may be bonded to a wiring substrate 310 by a wafer bonding by using a bonding metal layer 330 formed of a material such as Au-Au or AuSn, and thus the P-type electrode 226 and an N-type contact electrode 327 may be electrically connected to each other. In this regard, in order to achieve an electrical insulation, the wiring substrate 310 may have a structure in which a wiring circuit is formed on an insulating substrate formed of a material such as Si or AlN. In order to form a wiring structure, the P-type electrode 226 is formed on a lower surface, as shown in FIG. 10, the N-type electrode 327 is formed in a part of the N-type nitride semiconductor layer 221, and the P-type electrode 226 and the N-type electrode 327 may be electrically insulated from each other by an insulating layer 328.

A portion of the insulating layer 328 contacting the wiring substrate 310 is removed to expose the P-type electrode 226 and the N-type electrode 327.

In the current embodiment, the nitride epitaxial structures 320 may commonly include the N-type nitride semiconductor layer 221, but the present disclosure is not limited thereto. The N-type nitride semiconductor layer 221 may be formed in each of the individual light-emitting devices that are arranged in parallel.

It should be understood that the exemplary embodiments described herein should be considered in a descriptive sense only and not for purposes of limitation. Descriptions of features or aspects within each embodiment should typically be considered as available for other similar features or aspects in other embodiments.

What is claimed is:

1. A nitride light-emitting device comprising:
an N-type nitride semiconductor layer;
a P-type nitride semiconductor layer; and
an active layer disposed between the N-type nitride semiconductor layer and the P-type nitride semiconductor layer,
wherein the P-type nitride semiconductor layer includes:
a heterojunction structure comprising a GaN layer and an N-type AlₓIn_{y}GaN layer that is doped with an N-type dopant, wherein 0≦x≦1, 0≦y≦1, and x+y=1;and a two-dimensional electron gas (2DEG) layer disposed in an interface between the GaN layer and the N-type AlₓIn_{y}GaN layer.

2. The nitride light-emitting device of claim 1, wherein the P-type nitride semiconductor layer comprises a P-type clad layer formed on the active layer and a P-type contact layer formed on the P-type clad layer.

3. The nitride light-emitting device of claim 2, wherein the heterojunction structure is formed inside the P-type contact layer.

4. The nitride light-emitting device of claim 2, wherein the heterojunction structure is formed inside the P-type clad layer.

5. The nitride light-emitting device of claim 3, wherein the P-type contact layer comprises a first P-type contact layer deposed at an upper side of the heterojunction structure and a second P-type contact layer at a lower side of the heterojunction structure, and the first P-type contact layer and the second P-type contact layer have the same composition.

6. The nitride light-emitting device of claim 2, wherein the P-type contact layer is formed of P⁺-GaN.

7. The nitride light-emitting device of claim 1, wherein the P-type nitride semiconductor layer comprises a P-type clad layer disposed on the active layer and a P-type contact layer disposed on the P-type clad layer,
wherein the heterojunction structure is in the P-type clad layer.

8. The nitride light-emitting device of claim 1, wherein the GaN layer is formed at the active layer with the heterojunction structure.

9. The nitride light-emitting device of claim 1, wherein the GaN layer is an undoped layer.

10. The nitride light-emitting device of claim 1, wherein the GaN layer has a thickness of about 5 nm to about 50 nm.

11. The nitride light-emitting device of claim 1, wherein the GaN layer has a thickness of about 7 nm to about 15 nm.

12. The nitride light-emitting device of claim 1, wherein the N-type dopant of the N-type AlₓIn_{y}GaN layer is Si.

13. The nitride light-emitting device of claim 1, wherein the N-type AlₓIn_{y}GaN layer is formed of AlGaN comprising Al content of from about 15 to about 45%.

14. The nitride light-emitting device of claim 1, wherein the N-type AlₓIn_{y}GaN layer has a thickness of about 10 nm to about 50 nm.

15. The nitride light-emitting device of claim 1, wherein the N-type AlₓIn_{y}GaN layer has a thickness of about 15 nm to about 30 nm.

16. The nitride light-emitting device of claim 1, further comprising:
an N-type electrode disposed on the N-type nitride semiconductor layer; and
a P-type electrode disposed on the P-type nitride semiconductor layer and formed of a transparent conductive material,
wherein light is emitted through the P-type electrode.

17. The nitride light-emitting device of claim 1, further comprising:
an N-type electrode disposed on the N-type nitride semiconductor layer; and
a P-type electrode disposed on the P-type nitride semiconductor layer, wherein light is emitted through the N-type nitride semiconductor layer.

18. The nitride light-emitting device of claim 1, further comprising:
an N-type electrode disposed on the N-type nitride semiconductor layer; and
a P-type electrode disposed on the P-type nitride semiconductor layer.

19. A nitride light-emitting device comprising:
an N-type nitride semiconductor layer;
a P-type nitride semiconductor layer; and
an active layer disposed between the N-type nitride semiconductor layer and the P-type nitride semiconductor layer,
wherein the P-type nitride semiconductor layer includes:
a first P-type semiconductor layer disposed on the active layer;
a heterojunction structure comprising a GaN layer and an N-type AlₓIn_{y}GaN layer that is doped with an N-type dopant, wherein 0≦x≦1, 0≦y≦1, and x+y=1; and a two-dimensional electron gas (2DEG) layer disposed in an interface between the GaN layer and the N-type AlₓIn_{y}GaN layer; and
a second P-type semiconductor layer disposed on the heterojunction structure.
